(19) United States
(12) Patent Application Publication
(10) Pub. No.: US 2026/0096262 A1
(43) Pub. Date: Apr. 2, 2026

(54) MICRO LED PIXEL WITH MONOLITHIC ACTIVE MATRIX GALLIUM NITRIDE FIELD EFFECT TRANSISTORS AND POLYCHROMIC STACKED RGB MICROLEDS FOR DISPLAY

(71) Applicant: Lumileds LLC, San Jose, CA (US)

(72) Inventors: Frank Zhongmin Ren, Danville, CA (US); Robert Armitage, Cupertino, CA (US); Joseph Flemish, Palo Alto, CA (US)

(73) Assignee: Lumileds LLC, San Jose, CA (US)

(21) Appl. No.: 18/904,514

(22) Filed: Oct. 2, 2024

(51) Int. Cl. H01L 27/15

(52) U.S. Cl. CPC H10H 29/10

(57) ABSTRACT

Provided is a monolithic active matrix pixel with a polychromatic RGB micro-LED and field effect transistors (FET) on the same epitaxial wafer. The field effect transistors are gallium nitride (GaN)-based. The polychromatic RGB micro-LED is formed on a transistor channel layer on the epitaxial wafer. The polychromatic RGB micro-LED has four electrode terminals, one of which is a common anode or a common cathode.

### TECHNICAL FIELD

Embodiments of the disclosure generally relate to light-emitting diode (LED) devices and methods of manufacturing the same. More particularly, embodiments are directed to microLED pixels with monolithic active matrix gallium nitride (GaN) field effect transistors (FET) and polychromic stacked RGB microLEDs for displays.

### BACKGROUND

A light-emitting diode (LED) is a semiconductor light source that emits visible light when current flows through it. LEDs combine a P-type semiconductor with an N-type semiconductor. LEDs commonly use a III-V group compound semiconductor. A III-V group compound semiconductor provides stable operation at a higher temperature than devices that use other semiconductors. The III-V group compound is typically GaN based and formed on a substrate formed of sapphire, silicon, or silicon carbide (SiC).

High-resolution color LED displays require microscopic pixel pitches. Assembling red, green, and blue LEDs grown on separate wafers becomes difficult when the sizes of the LEDs are in the range of tens of microns. Monolithic integration is an approach that avoids the need to manipulate microscopic LEDs into the right positions on the display but comes with its own set of challenges.

Accordingly, there is a need for improved LED devices, specifically improved microLED display devices.

### SUMMARY

Embodiments of the disclosure are directed to LED devices and methods for manufacturing LED devices. In one or more embodiments, a light-emitting diode (LED) device comprises: a polychromatic epitaxial stack on a substrate, the polychromatic epitaxial stack including a first light-emitting active region, a second light-emitting active region, a third light-emitting active region, and a first current blocking layer; and at least three field effect transistors (FET) electrically connected to one of the first light-emitting active region, the second light-emitting active region, or the third light-emitting active region.

Additional embodiments of the disclosure are directed to methods of manufacturing LED devices. In one or more embodiments, a method of manufacturing a light-emitting diode (LED) die comprises: epitaxially growing a polychromatic epitaxial stack on a substrate, the polychromatic epitaxial stack including a first light-emitting active region, a second light-emitting active region, a third light-emitting active region, and a first current blocking layer; and electrically connecting each of the first light-emitting active region, the second light-emitting active region, and the third light-emitting active region to a field effect transistor (FET).

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments described herein are illustrated by way of example and not limited in the figures of the accompanying drawings in which like references indicate similar elements.

FIG. 1 illustrates a cross-sectional view of a microLED device showing the current blocking layers according to one or more embodiments;

FIG. 2 illustrates a cross-sectional view of a microLED device showing the current blocking layers according to one or more embodiments;

FIG. 3 illustrates a cross-sectional view of a microLED device showing the current blocking layers according to one or more embodiments;

FIG. 4 illustrates a cross-sectional view of a microLED device showing the current blocking layers according to one or more embodiments;

FIG. 5 illustrates a cross-sectional view of a microLED device showing the current blocking layers according to one or more embodiments; and

FIG. 6 illustrates a cross-sectional view of a microLED device showing the current blocking layers according to one or more embodiments.

To facilitate understanding, identical reference numerals have been used, where possible, to designate identical elements that are common to the figures. The figures are not drawn to scale. For example, the heights and widths of the layers are not drawn to scale.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term "substrate" as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate or on a substrate with one or more layers, films, features, or materials deposited or formed thereon.

In one or more embodiments, the "substrate" means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN, and other alloys), metal alloys, and other conductive materials, depending on the application. Substrates include, without limitation, light-emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed is also performed on an underlayer formed on the substrate, and the term "substrate surface" is intended to include such underlayer as the context indicates. Thus, for example, where a film/layer or partial film/layer has been deposited onto a substrate surface, the exposed surface of the newly deposited film/layer becomes the substrate surface.

The term "wafer" and "substrate" may be used interchangeably in the instant disclosure. Thus, as used herein, a wafer serves as the substrate for the formation of the LED devices described herein.

As used herein, the term "field-effect transistor" or "FET" refers to a type of transistor that uses an electric field to control the flow of current in a semiconductor. FETs have three terminals – source, gate, and drain. FETs control the flow of current by application of a voltage to the gate, which alters the conductivity between the drain and source. A "metal–oxide–semiconductor field-effect transistor" or "MOSFET" is a type of field-effect transistor (FET). It has an insulated gate, the voltage of which determines the conductivity of the device. This ability to change conductivity with the amount of applied voltage is used for amplifying or switching electronic signals.

Examples of different light illumination systems and/or light-emitting diode (LED) implementations may be described more fully hereinafter with reference to the accompanying drawings. These examples are not mutually exclusive, and features found in one example may be combined with features found in one or more other examples to achieve additional implementations. Accordingly, it may be understood that the examples shown in the accompanying drawings are provided for illustrative purposes only and they are not intended to limit the disclosure in any way. Like numbers refer to like elements throughout.

Semiconductor light-emitting devices or optical power emitting devices, such as devices that emit ultraviolet (UV) or infrared (IR) optical power, are among the most efficient light sources currently available. These devices may include light-emitting diodes, resonant cavity light-emitting diodes, vertical cavity laser diodes, edge emitting lasers, or the like (hereinafter referred to as "LEDs"). Due to their compact size and lower power requirements, for example, LEDs may be attractive candidates for many different applications. For example, they may be used as light sources (e.g., flashlights and camera flashes) for hand-held battery-powered devices, such as cameras and cell phones. They may also be used, for example, for automotive lighting, heads up display (HUD) lighting, horticultural lighting, street lighting, torch for video, general illumination (e.g., home, shop, office and studio lighting, theater/stage lighting and architectural lighting), augmented reality (AR) lighting, virtual reality (VR) lighting, as back lights for displays, and IR spectroscopy. A single LED may provide light that is less bright than an incandescent light source, and, therefore, multi-junction devices or arrays of LEDs (such as monolithic LED arrays, micro-LED arrays, etc.) may be used for applications where more brightness is desired or required.

The present disclosure generally relates to the manufacture of polychromatic LED devices that can be used in high resolution color displays. For microLED displays, a monolithic active matrix pixel with polychromic RGB micro-LED and transistors can advantageously simplify the fabrication process and reduce the cost. Polychromic stacked RGB microLEDs with a single epitaxial growth are provided. In addition to the benefit of polychromic RGB stacks, a monolithic active matrix can further add field effect transistors (FET).

In one or more embodiments, gallium nitride-based field-effect transistors (GaN-FET) are incorporated into the pixel and significantly integrate the display manufacturing processes and reduce costs. GaN-FET are formed on the same epitaxial wafer and wafer processing. In one or more embodiments, there is no need to attach microLEDs to display backplane panels because of monolithic GaN-FET on the same panel. Advantageously, no RGB die transfer processes are needed to make pixels for color displays. No RGB color combination optics are needed to make pixels for color displays, and no RGB field sequential driving schemes are needed to make pixels for color displays.

One or more embodiments provide an RGB color display panel together with monolithic GaN-FET transistors to enable active matrix display from a single epitaxial wafer without die transfer or epitaxial wafer bonding techniques. The display manufacturing processes are integrated and costs are reduced.

The GaN-FET transistors and RGB stacked epitaxial wafer of one or more embodiments are used to fabricate color display panels. Each pixel has GaN-FET transistors to simultaneously and individually control each stacked RGB emissive active region to realize an active matrix display.

In one or more embodiments, an RGB stacked InGaN epitaxial wafer together with GaN-FET layer with engineered GaN-FET channel doping profiles is used to fabricate color display panels. In one or more embodiments, each pixel has three or more GaN-FET transistors and one RGB microLED or with another RGB microLED as redundancy.

In one or more embodiments, the GaN-FET transistor can be formed by a FET channel of intrinsic or low-level n-doped GaN. The doping profile may be engineered to realize FET functions as well as good ohmic contacts at source and drain. The GaN-FET channel may be formed by a FET channel etch. The FET channel etch and subsequent surface cleaning may be optimized to minimize surface damages and to reduce current leakages, charge retentions, hysteresis effects. The GaN-FET fabrication of one or more embodiments is compatible with microLED fabrication processes.

In one or more embodiments, each microLED in a pixel has stacked RGB emissive active regions which are electrically isolated from each other to avoid interactions of driving circuits. The LED electrical isolation is realized by inserting a current blocking layer (i.e., a semi-insulated layer) between active regions.

In one or more embodiments, the FET electrical isolation may be achieved by etching the extraneous channel layer surrounding the active portion of the FET, or by selectively rendering the surrounding regions insulating through ion implantation.

In one or more embodiments, the wafer fabrication process includes mesa etches to make p- and n-contacts for each color; epitaxial anneal to activate dopant tunnel junctions, die isolation etches, FET channel etch, PECVD, and atomic layer deposition, and metallization.

In one or more embodiments, for high density displays, such as, but not limited to, augmented reality displays, processes could include copper (Cu) or gold (Au) plating processes with seeding layers, chemical mechanical polishing, hybrid bonding, and the like.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

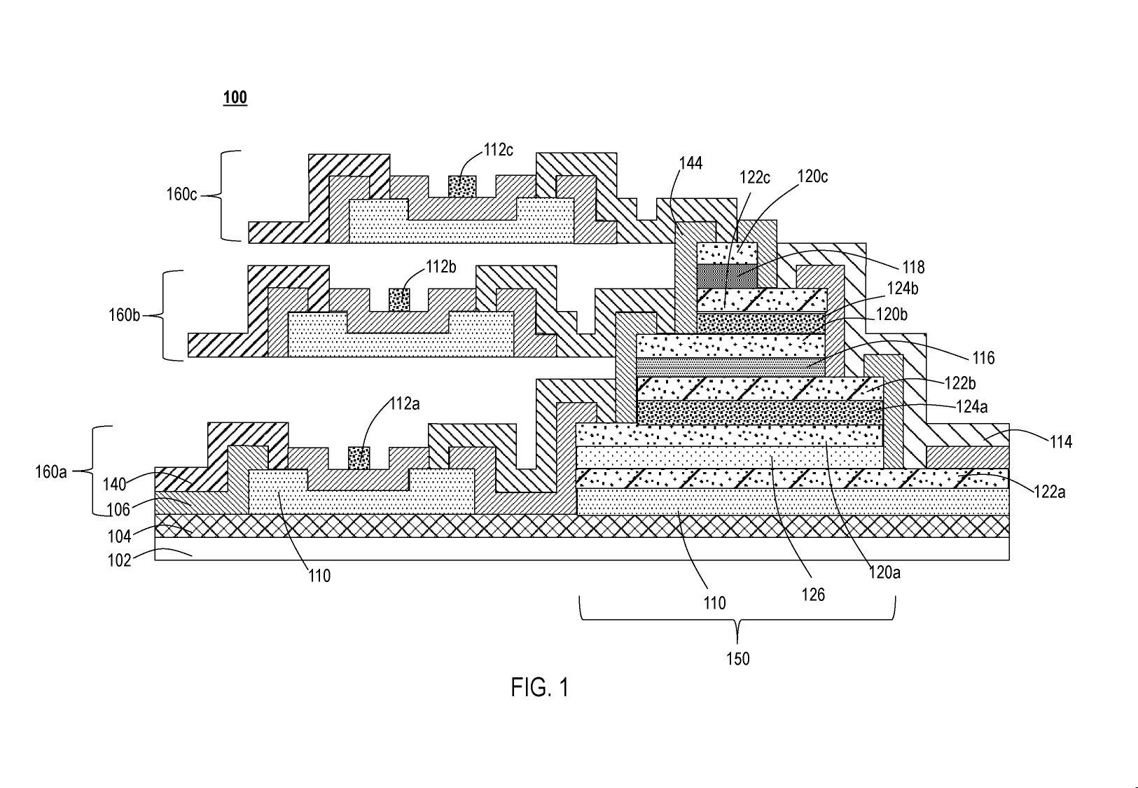

One or more embodiments of the disclosure are described with reference to the Figures. FIG. 1 shows a common cathode 114 connected to each RGB stack 150. In one or more embodiments, each LED 126, 116, 118 of the RGB stack 150 is connected via an electrode 144 to a FET transistor 160a, 160b, 160c to form the device 100. Advantageously, the device 100 does not need to be attached to a display backplane due to the presence of the FET Drive (or Data) transistors 160a, 160b, 160c on the same substate 102. Any other transistors, such as Select (or Scan) transistors, which control Drive transistors and any other additional transistors to compensate for the instability of the Drive transistors, can be fabricated in the same way on the same epi substrate. In one or more embodiments, there are four electrode terminals per RGB stack 150. Each RGB stack 150 has two current blocking layers - a first current blocking layer 124a and a second current blocking layer 124b.

Referring to FIG. 1, an RGB stack 150 is formed on a substrate 102. In one or more embodiments, a nucleation layer 104 and dislocation density control layers (not illustrated) may be grown on a suitable substrate 102, such as patterned or non-patterned sapphire. In one or more embodiments, the nucleation layer comprises a III-nitride material. In specific embodiments, the nucleation layer 104 comprises gallium nitride (GaN) or aluminum nitride (AlN).

The substrate 102 may be any substrate known to one of skill in the art which is configured for use in the formation of LED devices. In one or more embodiments, the substrate 102 comprises one or more of sapphire, silicon carbide, silicon (Si), quartz, magnesium oxide (MgO), zinc oxide (ZnO), spinel, and the like. In one or more embodiments, the substrate 102 is a transparent substrate. In specific embodiments, the substrate 102 comprises sapphire. In one or more embodiments, the substrate 102 is not patterned prior to formation of the LEDs. Thus, in some embodiments, the substrate is 102 not patterned and can be considered to be flat or substantially flat. In other embodiments, the substrate 102 is a patterned substrate.

A transistor channel layer 110 is then formed on the nucleation layer 104. The transistor channel layer 110 may comprise any suitable material known to the skilled artisan. In one or more embodiments, the transistor channel layer 110 comprises any Group III-V semiconductor material, including binary, ternary, and quaternary alloys of gallium (Ga), aluminum (Al), indium (In), and nitrogen (N), also referred to as III-nitride materials. In specific embodiments, the transistor channel layer 110 comprises gallium nitride (GaN).

In one or more embodiments a first cathode 122a is formed on the transistor channel layer 110. The first cathode 122a may comprise any suitable material known to the skilled artisan. In one or more embodiments, the first cathode 122a may be any n-doped III-nitride material. In specific embodiments, the first cathode 122a comprises n-doped gallium nitride (GaN). The first LED 126 is formed on the first cathode 122a. The first LED 126 may comprise any suitable number of n-type layers, p-type layers, active layers, and tunnel junctions.

In one or more embodiments, the n-type layers and p-type layers of the first LED 126 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the first LED 126 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the first LED 126 may be doped or undoped and have any suitable thickness.

A tunnel junction is a structure that allows electrons to tunnel from the valence band of a p-type layer to the conduction band of an n-type layer in reverse bias. When an electron tunnels, a hole is left behind in the p-type layer, such that carriers are generated in both regions.

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD).

"Sputter deposition" as used herein refers to a physical vapor deposition (PVD) method of thin film deposition by sputtering. In sputter deposition, a material, e.g., a III-nitride, is ejected from a target that is a source onto a substrate. The technique is based on ion bombardment of a source material, the target. Ion bombardment results in a vapor due to a purely physical process, i.e., the sputtering of the target material.

As used according to some embodiments herein, "atomic layer deposition" (ALD) or "cyclical deposition" refers to a vapor phase technique used to deposit thin films on a substrate surface. The process of ALD involves the surface of a substrate, or a portion of substrate, being exposed to alternating precursors, i.e., two or more reactive compounds, to deposit a layer of material on the substrate surface. When the substrate is exposed to the alternating precursors, the precursors are introduced sequentially or simultaneously. The precursors are introduced into the reaction zone of a processing chamber, and the substrate, or portion of the substrate, is exposed separately to the precursors.

As used herein according to some embodiments, "chemical vapor deposition" refers to a process in which films of materials are deposited from the vapor phase by decomposition of chemicals on a substrate surface. In CVD, a substrate surface is exposed to precursors and/or co-reagents simultaneously or substantially simultaneously. A particular subset of CVD processes commonly used in LED manufacturing use metalorganic precursor chemical and are referred to as MOCVD or metalorganic vapor phase epitaxy (MOVPE). As used herein, "substantially simultaneously" refers to either co-flow or where there is overlap for a majority of exposures of the precursors.

As used herein according to some embodiments, "plasma enhanced atomic layer deposition (PEALD)" refers to a technique for depositing thin films on a substrate. In some examples of PEALD processes relative to thermal ALD processes, a material may be formed from the same chemical precursors, but at a higher deposition rate and a lower temperature. In a PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g., a thin film on a substrate. Similar to a thermal ALD process, a purge step may be conducted between the deliveries of each of the reactants.

As used herein according to one or more embodiments, "plasma enhanced chemical vapor deposition (PECVD)" refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

In one or more embodiments, first LED 126 is manufactured by placing the substrate 102 in a metalorganic vapor-phase epitaxy (MOVPE) reactor so that the µLED array layers are grown epitaxially.

In one or more embodiments, the first LED 126 includes a first light-emitting active region. In one or more embodiments, the first LED 126 includes a first light-emitting active region that is a blue active region. The first light-emitting active region may include multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for blue LEDs ranges from 1 to 12, the typical barrier thickness ranges from 3 nm to 20 nm, the well thickness ranges from 1 nm to 5 nm, and the well indium concentration ranges from 10% indium to 20% indium. In some embodiments, the active region(s) may be doped with Si or Ge, while in other embodiments, the active region(s) is undoped.

Referring to FIG. 1, a first anode 120a is formed on the first LED 126. In one or more embodiments, the first anode 120a may comprise any suitable material known to the skilled artisan. In one or more embodiments, the first anode 120a could be any suitable p-doped III-nitride material. In specific embodiments, the first anode 120a comprises p-doped gallium nitride (GaN). A first current blocking layer 124a is the formed on the first anode 120a.

In one or more embodiments, the current blocking layers described herein may be comprised of one or more of a p-type layer, a weakly n-type (semi-insulating) layer, or a layer of different semiconductor alloy composition exhibiting a conduction band offset of more than 0.1 eV with respect to the adjacent n-type layers, such as an AlGaN or InGaN layer sandwiched between n-type GaN layers. Semi-insulating layers may be realized by doping with deep-level impurities such as carbon or iron, at a concentration equal to or greater than the total concentration of donor impurities, e.g., silicon (Si), germanium (Ge), and oxygen (O).

In one or more embodiments, a second LED 116 is formed on the first current blocking layer 124a. The second LED 116 may comprise any suitable number of n-type layers, p-type layers, active layers, and tunnel junctions.

In one or more embodiments, the n-type layers and p-type layers of the second LED 116 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the second LED 116 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the second LED 116 may be doped or undoped and have any suitable thickness.

In one or more embodiments, the second LED 116 includes a second light-emitting active region. In one or more embodiments, the second LED 116 includes a second light-emitting active region that is a green active region. A second anode 120b is formed on the second LED 116.

Still referring to FIG. 1, in one or more embodiments, a second current blocking layer 124b is formed on the second anode 120b. A third cathode 122c is formed on the second current blocking layer 124b, and a third LED 118 is formed on the third cathode 122c.

The third LED 118 may comprise any suitable number of n-type layers, p-type layers, active layers, and tunnel junctions. In one or more embodiments, the n-type layers and p-type layers of the third LED 118 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the third LED 118 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the third LED 118 may be doped or undoped and have any suitable thickness.

In one or more embodiments, the third LED 118 includes a third light-emitting active region. In one or more embodiments, the third LED 118 includes a third light-emitting active region that is a red active region. A third anode 120c is formed on the third LED 118.

Referring to FIG. 1, each FET transistor 160a, 160b, 160c of the device 100 includes the transistor channel layer 110, which extends between a source and drain region. A dielectric layer 106 is formed on the transistor channel layer 110 of the FET transistor 160a, 160b, 160c and on the RGB stack 150. Each FET transistor 160a, 160b, 160c includes a gate 112a, 112b, 112c on the dielectric layer 106. In one or more embodiments, the gate 112a, 112b, 112c may comprise any suitable material known to the skilled artisan. In one or more embodiments, the gate 112a, 112b, 112c may be a metal, such as, but not limited to, aluminum (Al), titanium (Ti), molybdenum (Mo), chromium (Cr), gold (Au), or nickel (Ni), or metal compounds thereof. An anode 140 is formed on the dielectric layer 106 of each FET transistor 160a, 160b, 160c. In one or more embodiments, the anode 140 may comprise any suitable material known to the skilled artisan. In one or more embodiments, the anode 140 may include a metal, such as, but not limited to, aluminum (Al), titanium (Ti), molybdenum (Mo), chromium (Cr), gold (Au), or nickel (Ni), or metal compounds thereof.

As used herein, the term "dielectric" refers to an electrical insulator material that can be polarized by an applied electric field. In one or more embodiments, the dielectric layers described herein include, but are not limited to, oxides, e.g., silicon oxide (SiO₂), aluminum oxide (Al₂O₃), nitrides, e.g., silicon nitride (Si₃N₄). In one or more embodiments, the dielectric layer comprises silicon nitride (Si₃N₄), silicon oxide (SiO₂), or a multi-layer of silicon dioxide (SiO₂) and silicon nitride (Si₃N₄). In some embodiments, the dielectric layer composition is non-stoichiometric relative to the ideal molecular formula. For example, in some embodiments, the dielectric layer includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

In one or more embodiments, the dielectric layer 106 is patterned using lithography and wet or dry etching to leave openings for metal to contact the semiconductor at desired locations. In one or more embodiments, a portion of the dielectric layer 106 is removed with dry etching to form an opening where a cathode metal or an anode metal is deposited. Contact metals are typically deposited in the openings after dielectric layer 106 patterning using a physical vapor deposition (PVD) technique such as evaporation or sputtering.

A cathode metal may be deposited into the opening, which is lined with dielectric layer 106. The cathode metal may comprise any suitable material known to the skilled artisan. In one or more embodiments, the cathode metal is any high reflectivity metal that makes ohmic contact with the n-type layers of the first LED. In one or more specific embodiments, the cathode metal comprises an n-contact material selected from one or more of silver (Ag) and aluminum (Al). In one or more embodiments, the cathode metal may form a common cathode.

An anode metal may be deposited into the opening, which is lined with dielectric layer 106. The anode metal may comprise any suitable material known to the skilled artisan. In one or more embodiments, the anode metal is any high reflectivity metal that makes ohmic contact with the n-type layers of the first LED. In one or more specific embodiments, the anode metal comprises an n-contact material selected from one or more of silver (Ag) and aluminum (Al). In one or more embodiments, the anode metal may form a common anode.

In one or more embodiments, a source FET can also be fabricated in the same way as the drive FET (or the “FET” described above). Each color LED (or the first or second or the third LED) will have one Drive FET (as shown in FIG. 1) and one or more Select FET to control the operation of the LED such as the drive current, pulse durations and turn on time. This can realize a monolithic device with LEDs and transistors on the sample epi wafer and therefore no need TFT or CMOS pixel drives.

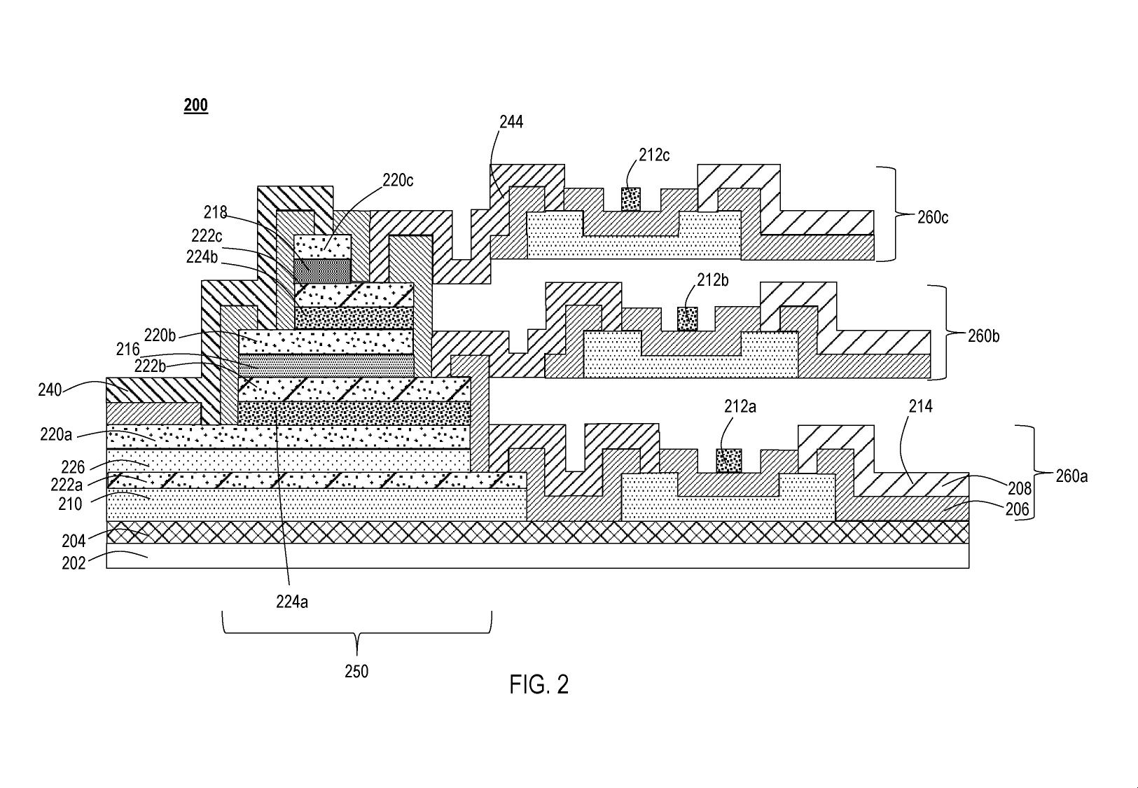

FIG. 2 shows a common anode 240 connected to each RGB stack 250. In one or more embodiments, each LED of the RGB stack 250 is connected an electrode 244 to a FET transistor 260a, 260b, 260c to form the device 200. Advantageously, the device 200 does not need to be attached to a display backplane due to the presence of the FET transistors 260a, 260b, 260c on the same substate 202. Any other transistors, such as Select (or Scan) transistors, which controls Drive transistors, and any other additional transistors to compensate for the instability of the Drive transistors, can be fabricated in the same way on the same epi substrate. In one or more embodiments, there are four electrode terminals per microLED 200. Each RGB stack 250 has two current blocking layers - a first current blocking layer 224a and a second current blocking layer 224b.

Referring to FIG. 2, an RGB stack 250 is formed on a substrate 202. In one or more embodiments, a nucleation layer 204 and dislocation density control layers (not illustrated) may be grown on a suitable substrate 202, such as patterned or non-patterned sapphire as described above. In one or more embodiments, the nucleation layer comprises a III-nitride material. In specific embodiments, the nucleation layer 204 comprises gallium nitride (GaN) or aluminum nitride (AlN).

A transistor channel layer 210 is then formed on the nucleation layer 204. The transistor channel layer 210 may comprise any suitable material known to the skilled artisan. In one or more embodiments, the transistor channel layer 210 comprises any Group III-V semiconductor material, including binary, ternary, and quaternary alloys of gallium (Ga), aluminum (Al), indium (In), and nitrogen (N), also referred to as III-nitride materials. In specific embodiments, the transistor channel layer 210 comprises gallium nitride (GaN).

In one or more embodiments a first cathode 222a is formed on the transistor channel layer 210. The first LED 226 is formed on the first cathode 222a. The first LED 226 may comprise any suitable number of n-type layers, p-type layers, active layers, and tunnel junctions.

In one or more embodiments, the n-type layers and p-type layers of the first LED 226 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the first LED 226 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the first LED 226 may be doped or undoped and have any suitable thickness.

In one or more embodiments, first LED 226 is manufactured by placing the substrate 202 in a metalorganic vapor-phase epitaxy (MOVPE) reactor so that the µLED array layers are grown epitaxially.

In one or more embodiments, the first LED 226 includes a first light-emitting active region. In one or more embodiments, the first LED 226 includes a first light-emitting active region that is a blue active region. The first light-emitting active region may include multiple quantum wells and may include electron blocking layer(s) grown after the quantum wells and strain-control layers grown before the quantum wells. The number of quantum wells typically used for blue LEDs ranges from 1 to 12, the typical barrier thickness ranges from 3 nm to 20 nm, the well thickness ranges from 1 nm to 5 nm, and the well indium concentration ranges from 10% indium to 20% indium. In some embodiments, the active region(s) may be doped with Si or Ge, while in other embodiments, the active region(s) is undoped.

Referring to FIG. 2, a first anode 220a is formed on the first LED 226. A first current blocking layer 224a is the formed on the first anode 220a. In one or more embodiments, a second cathode 222b is formed on the first current blocking layer 224a.

In one or more embodiments, a second LED 216 is formed on the second cathode 222b. The second LED 216 may comprise any suitable number of n-type layers, p-type layers, active layers, and tunnel junctions.

In one or more embodiments, the n-type layers and p-type layers of the second LED 216 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the second LED 216 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the second LED 216 may be doped or undoped and have any suitable thickness.

In one or more embodiments, the second LED 216 includes a second light-emitting active region. In one or more embodiments, the second LED 216 includes a second light-emitting active region that is a green active region. A second anode 220b is formed on the second LED 216.

Still referring to FIG. 2, in one or more embodiments, a second current blocking layer 224b is formed on the second anode 220b. A third cathode 222c is formed on the second current blocking layer 224b, and a third LED 218 is formed on the third cathode 222c.

The third LED 218 may comprise any suitable number of n-type layers, p-type layers, active layers, and tunnel junctions. In one or more embodiments, the n-type layers and p-type layers of the third LED 218 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the third LED 218 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the third LED 218 may be doped or undoped and have any suitable thickness.

In one or more embodiments, the third LED 218 includes a third light-emitting active region. In one or more embodiments, the third LED 218 includes a third light-emitting active region that is a red active region. A third anode 220c is formed on the third LED 218.

Referring to FIG. 2, each FET transistor 260a, 260b, 260c of the device 200 includes the transistor channel layer 210, which extends between a source and drain region. A dielectric layer 206 is formed on the transistor channel layer 210 of the FET transistor 260a, 260b, 260c and on the RGB stack 250. Each FET transistor 260a, 260b, 260c includes a gate 212a, 212b, 212c on the dielectric layer 206. An electrode terminal 244 is formed on each FET transistor 260a, 260b, 260c and connects each FET transistor to an LED of the RGB stack 250. Each FET transistor 260a, 260b, 260c also is connected to a cathode terminal 214.

In one or more embodiments, a source FET can also be fabricated in the same way as the drive FET (or the “FET” described above). Each color LED (or the first or second or the third LED) will have one Drive FET (as shown in FIG. 2) and one or more Select FET to control the operation of the LED such as the drive current, pulse durations and turn on time. This can realize a monolithic device with LEDs and transistors on the sample epi wafer and therefore no need TFT or CMOS pixel drives.

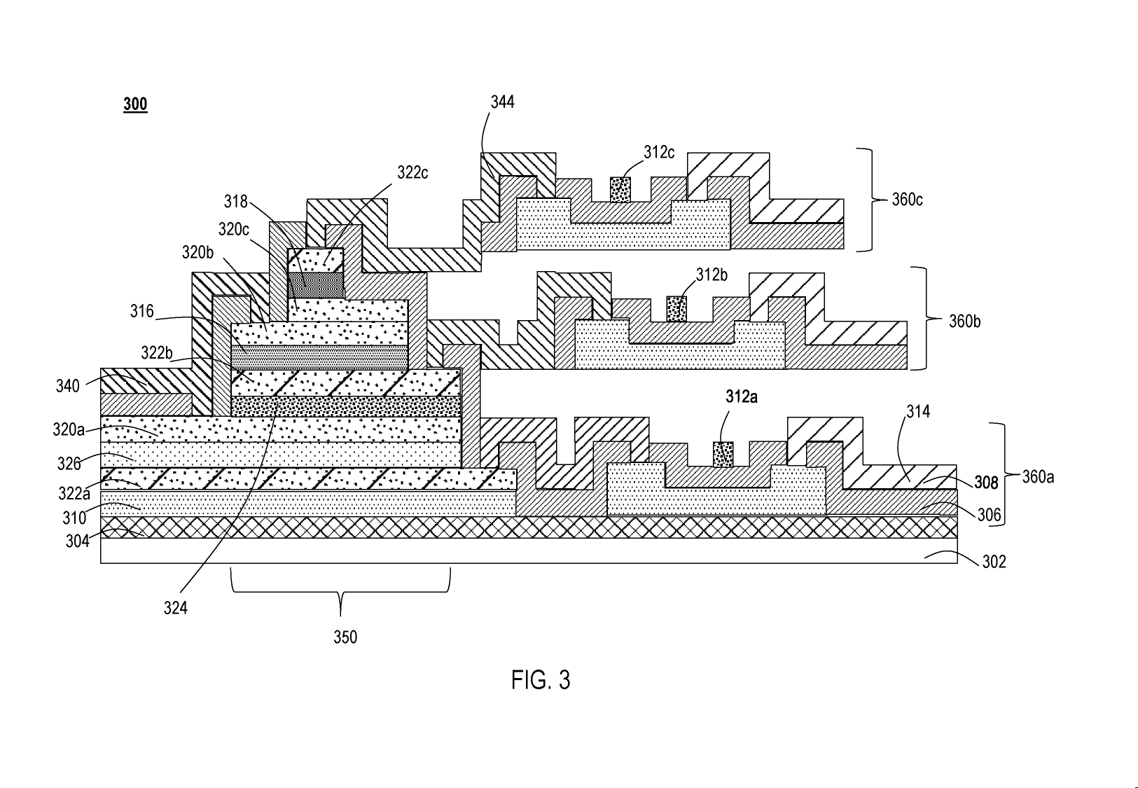

FIG. 3 shows a common anode 340 connected to each RGB stack 350. In one or more embodiments, each LED of the RGB stack 350 is connected via an electrode 344 to a FET transistor 360a, 360b, 360c to form the device 300. Advantageously, the device 300 does not need to be attached to a display backplane due to the presence of the FET transistors 360a, 360b, 360c on the same substate 302 as the RGB stack 350. Any other transistors, such as Select (or Scan) transistors, which control Drive transistors, and any other additional transistors to compensate for the instability of the Drive transistors, can be fabricated in the same way on the same epi substrate. In one or more embodiments, there are four electrode terminals per RGB stack 350. Each RGB stack 350 has a single current blocking layer 324. Each FET transistor 360a, 360b, 360c also is connected to a cathode terminal 314.

Referring to FIG. 3, an RGB stack 350 is formed on a substrate 302. In one or more embodiments, a nucleation layer 304 and dislocation density control layers (not illustrated) may be grown on a suitable substrate 302, such as patterned or non-patterned sapphire as described above. In one or more embodiments, the nucleation layer comprises a III-nitride material. In specific embodiments, the nucleation layer 304 comprises gallium nitride (GaN) or aluminum nitride (AlN).

A transistor channel layer 310 is then formed on the nucleation layer 304. The transistor channel layer 310 may comprise any suitable material known to the skilled artisan. In one or more embodiments, the transistor channel layer 310 comprises any Group III-V semiconductor material, including binary, ternary, and quaternary alloys of gallium (Ga), aluminum (Al), indium (In), and nitrogen (N), also referred to as III-nitride materials. In specific embodiments, the transistor channel layer 310 comprises gallium nitride (GaN).

In one or more embodiments a first cathode 322a is formed on the transistor channel layer 310. The first LED 326 is formed on the first cathode 322a. The first LED 326 may comprise any suitable number of n-type layers, p-type layers, active layers, and tunnel junctions.

In one or more embodiments, the n-type layers and p-type layers of the first LED 326 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the first LED 326 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the first LED 326 may be doped or undoped and have any suitable thickness.

In one or more embodiments, first LED 326 is manufactured by placing the substrate 302 in a metalorganic vapor-phase epitaxy (MOVPE) reactor so that the µLED array layers are grown epitaxially.

In one or more embodiments, the first LED 326 includes a first light-emitting active region. In one or more embodiments, the first LED 326 includes a first light-emitting active region that is a blue active region. The first light-emitting active region may include multiple quantum wells and may include electron blocking layer(s) grown after the quantum wells and strain-control layers grown before the quantum wells. The number of quantum wells typically used for blue LEDs ranges from 1 to 12, the typical barrier thickness ranges from 3 nm to 20 nm, the well thickness ranges from 1 nm to 5 nm, and the well indium concentration ranges from 10% indium to 20% indium. In some embodiments, the active region(s) may be doped with Si or Ge, while in other embodiments, the active region(s) is undoped.

Referring to FIG. 3, a first anode 320a is formed on the first LED 326. A current blocking layer 324 is the formed on the first anode 320a. In one or more embodiments, a second cathode 322b is formed on the current blocking layer 324.

In one or more embodiments, a second LED 316 is formed on the second cathode 322b. The second LED 316 may comprise any suitable number of n-type layers, p-type layers, active layers, and tunnel junctions.

In one or more embodiments, the n-type layers and p-type layers of the second LED 316 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the second LED 316 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the second LED 316 may be doped or undoped and have any suitable thickness.

In one or more embodiments, the second LED 316 includes a second light-emitting active region. In one or more embodiments, the second LED 316 includes a second light-emitting active region that is a green active region. A second anode 320b is formed on the second LED 316.

Still referring to FIG. 3, in one or more embodiments, a third anode 320c is formed on the second anode 320b, and a third LED 318 is formed on the third anode 320c.

The third LED 318 may comprise any suitable number of n-type layers, p-type layers, active layers, and tunnel junctions. In one or more embodiments, the n-type layers and p-type layers of the third LED 318 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the third LED 318 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the third LED 318 may be doped or undoped and have any suitable thickness.

In one or more embodiments, the third LED 318 includes a third light-emitting active region. In one or more embodiments, the third LED 318 includes a third light-emitting active region that is a red active region. A third cathode 322c is formed on the third LED 318.

Referring to FIG. 3, the FET transistors 360a, 360b, 360c of the device 300 includes the transistor channel layer 310, which extends between a source and drain region. A dielectric layer 306 is formed on the transistor channel layer 310 of the FET transistors 360a, 360b, 360c and on the RGB stack 350. Each of the FET transistors 360a, 360b, 360c includes a gate 312a, 312b, 312c on the dielectric layer 306. An electrode terminal 344 is formed on each FET transistor 360a, 360b, 360c and connects to one of the LEDs of the RGB stack 350.

In one or more embodiments, a source FET can also be fabricated in the same way as the drive FET (or the “FET” described above). Each color LED (or the first or second or the third LED) will have one Drive FET (as shown in FIG. 3) and one or more Select FET to control the operation of the LED such as the drive current, pulse durations and turn on time. This can realize a monolithic device with LEDs and transistors on the sample epi wafer and therefore no need TFT or CMOS pixel drives.

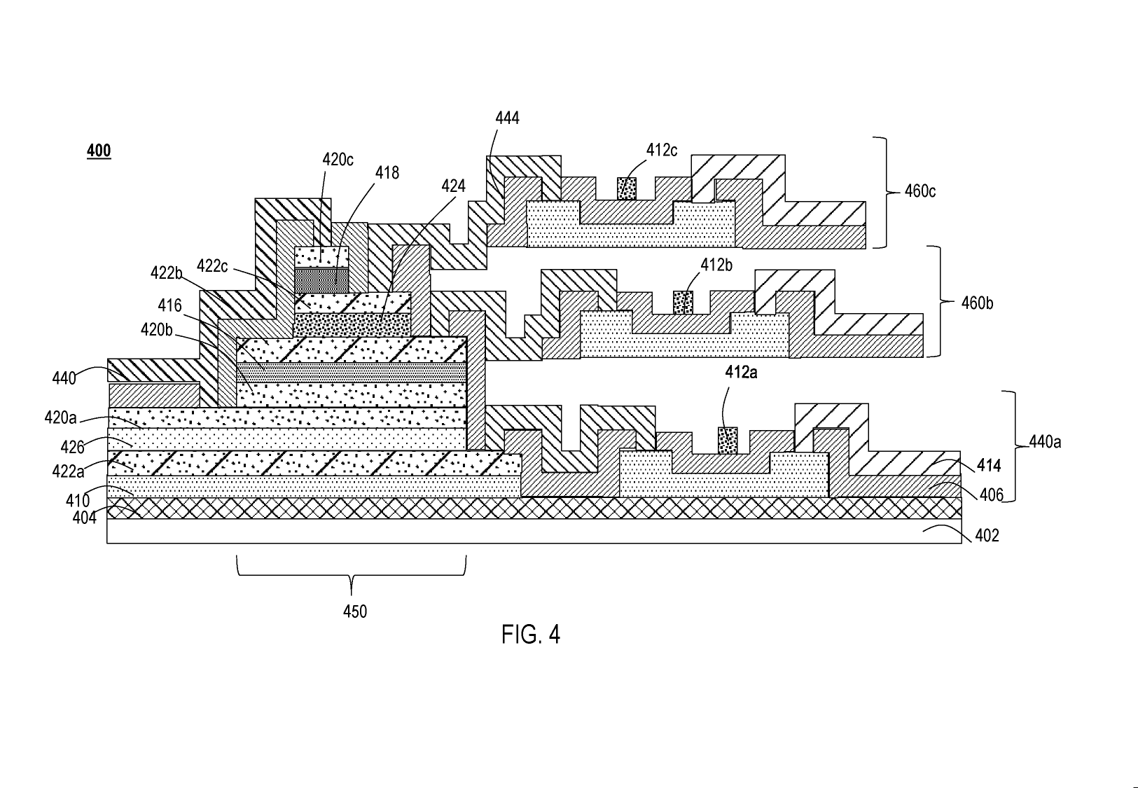

FIG. 4 shows a common anode 440 connected to each RGB stack 450. In one or more embodiments, each LED of the RGB stack 450 is connected via an electrode terminal 444 to a FET transistor 460a, 460b, 460c to form the device 400. Advantageously, the device 400 does not need to be attached to a display backplane due to the presence of the FET transistors 460a, 460b, 460c on the same substate 402 as the RGB stack 450. Any other transistors, such as Select (or Scan) transistors, which control Drive transistors, and any other additional transistors to compensate for the instability of the Drive transistors, can be fabricated in the same way on the same epi substrate. In one or more embodiments, there are four electrode terminals per RGB stack 450. Each RGB stack 450 has a single current blocking layer 424. Each FET transistor 460a, 460b, 460c also is connected to a cathode terminal 414.

Referring to FIG. 4, an RGB stack 450 is formed on a substrate 402. In one or more embodiments, a nucleation layer 404 and dislocation density control layers (not illustrated) may be grown on a suitable substrate 402, such as patterned or non-patterned sapphire as described above. In one or more embodiments, the nucleation layer comprises a III-nitride material. In specific embodiments, the nucleation layer 404 comprises gallium nitride (GaN) or aluminum nitride (AlN).

A transistor channel layer 410 is then formed on the nucleation layer 404. The transistor channel layer 410 may comprise any suitable material known to the skilled artisan. In one or more embodiments, the transistor channel layer 410 comprises any Group III-V semiconductor material, including binary, ternary, and quaternary alloys of gallium (Ga), aluminum (Al), indium (In), and nitrogen (N), also referred to as III-nitride materials. In specific embodiments, the transistor channel layer 410 comprises gallium nitride (GaN).

In one or more embodiments a first cathode 422a is formed on the transistor channel layer 410. The first LED 426 is formed on the first cathode 422a. The first LED 426 may comprise any suitable number of n-type layers, p-type layers, active layers, and tunnel junctions.

In one or more embodiments, the n-type layers and p-type layers of the first LED 426 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the first LED 426 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the first LED 426 may be doped or undoped and have any suitable thickness.

In one or more embodiments, first LED 426 is manufactured by placing the substrate 402 in a metalorganic vapor-phase epitaxy (MOVPE) reactor so that the µLED array layers are grown epitaxially.

In one or more embodiments, the first LED 426 includes a first light-emitting active region. In one or more embodiments, the first LED 426 includes a first light-emitting active region that is a blue active region. The first light-emitting active region may include multiple quantum wells and may include electron blocking layer(s) grown after the quantum wells and strain-control layers grown before the quantum wells. The number of quantum wells typically used for blue LEDs ranges from 1 to 12, the typical barrier thickness ranges from 3 nm to 20 nm, the well thickness ranges from 1 nm to 5 nm, and the well indium concentration ranges from 10% indium to 20% indium. In some embodiments, the active region(s) may be doped with Si or Ge, while in other embodiments, the active region(s) is undoped.

Referring to FIG. 4, a first anode 420a is formed on the first LED 426. A second anode 420b is the formed on the first anode 420a.

In one or more embodiments, a second LED 416 is formed on the second anode 420b. The second LED 416 may comprise any suitable number of n-type layers, p-type layers, active layers, and tunnel junctions.

In one or more embodiments, the n-type layers and p-type layers of the second LED 416 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the second LED 416 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the second LED 416 may be doped or undoped and have any suitable thickness.

In one or more embodiments, the second LED 416 includes a second light-emitting active region. In one or more embodiments, the second LED 416 includes a second light-emitting active region that is a green active region. A second cathode 422b is formed on the second LED 416.

Still referring to FIG. 4, in one or more embodiments, a current blocking layer 424 is formed on the second cathode 422b. A third cathode 422c is formed on the current blocking layer 424, and a third LED 418 is formed on the third cathode 422c.

The third LED 418 may comprise any suitable number of n-type layers, p-type layers, active layers, and tunnel junctions. In one or more embodiments, the n-type layers and p-type layers of the third LED 418 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the third LED 418 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the third LED 418 may be doped or undoped and have any suitable thickness.

In one or more embodiments, the third LED 418 includes a third light-emitting active region. In one or more embodiments, the third LED 418 includes a third light-emitting active region that is a red active region. A third anode 420c is formed on the third LED 418.

Referring to FIG. 4, the FET transistors 460a, 460b, 460c of the device 400 includes the transistor channel layer 410, which extends between a source and drain region. A dielectric layer 406 is formed on the transistor channel layer 410 of the FET transistors 460a, 460b, 460c and on the RGB stack 450. Each of the FET transistors 460a, 460b, 460c includes a gate 412a, 412b, 412c on the dielectric layer 406. An electrode terminal 444 is formed on each FET transistor 460a, 460b, 460c and connects to one of the LEDs of the RGB stack 450.

In one or more embodiments, a source FET can also be fabricated in the same way as the drive FET (or the “FET” described above). Each color LED (or the first or second or the third LED) will have one Drive FET (as shown in FIG. 4) and one or more Select FET to control the operation of the LED such as the drive current, pulse durations and turn on time. This can realize a monolithic device with LEDs and transistors on the sample epi wafer and therefore no need TFT or CMOS pixel drives.

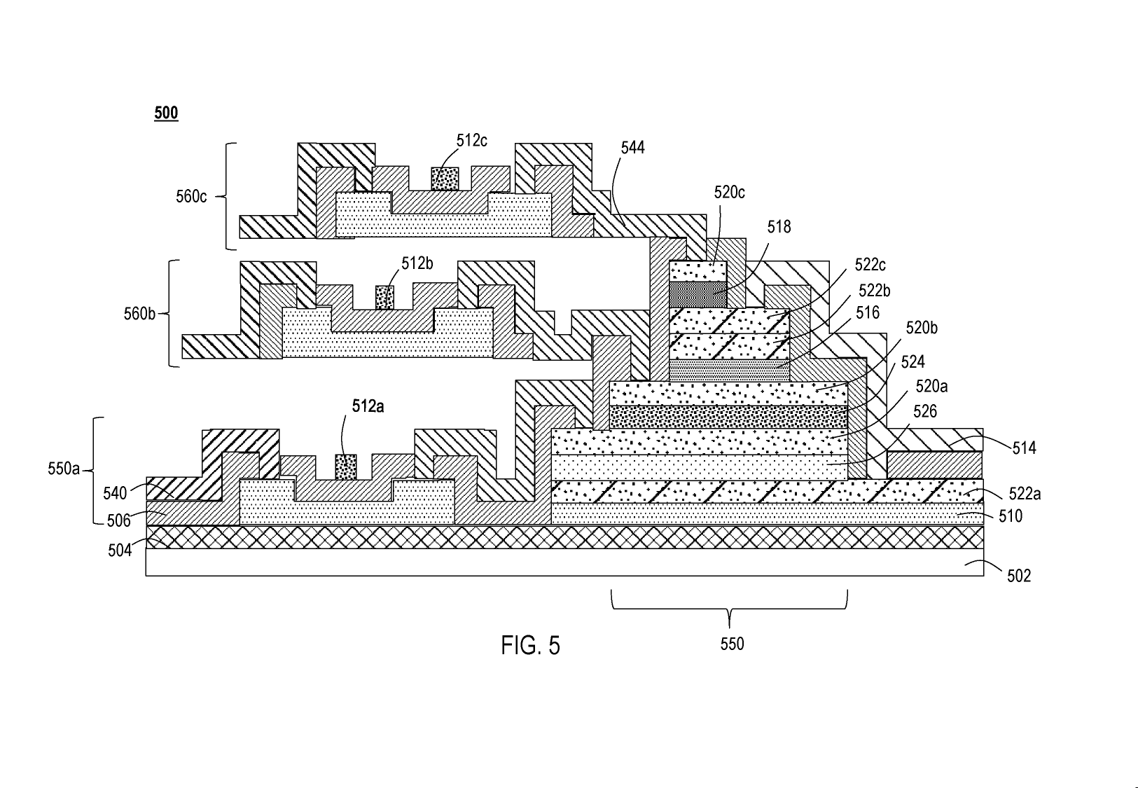

FIG. 5 shows a common cathode 514 connected to each RGB stack 550. In one or more embodiments, each LED of the RGB stack 550 is connected via an electrode terminal 544 to a FET transistor 560a, 560b, 560c to form the device 500. Advantageously, the device 500 does not need to be attached to a display backplane due to the presence of the FET transistors 560a, 560b, 560c on the same substate 502 as the RGB stack 550. Any other transistors, such as Select (or Scan) transistors, which control Drive transistors and any other additional transistors to compensate for the instability of the Drive transistors, can be fabricated in the same way on the same epi substrate. In one or more embodiments, there are four electrode terminals per RGB stack 550. Each RGB stack 550 has a single current blocking layer 524. Each FET transistor 560a, 560b, 560c also is connected to an anode terminal 540.

Referring to FIG. 5, an RGB stack 550 is formed on a substrate 502. In one or more embodiments, a nucleation layer 504 and dislocation density control layers (not illustrated) may be grown on a suitable substrate 502, such as patterned or non-patterned sapphire as described above. In one or more embodiments, the nucleation layer comprises a III-nitride material. In specific embodiments, the nucleation layer 504 comprises gallium nitride (GaN) or aluminum nitride (AlN).

A transistor channel layer 510 is then formed on the nucleation layer 504. The transistor channel layer 510 may comprise any suitable material known to the skilled artisan. In one or more embodiments, the transistor channel layer 510 comprises any Group III-V semiconductor material, including binary, ternary, and quaternary alloys of gallium (Ga), aluminum (Al), indium (In), and nitrogen (N), also referred to as III-nitride materials. In specific embodiments, the transistor channel layer 510 comprises gallium nitride (GaN).

In one or more embodiments a first cathode 522a is formed on the transistor channel layer 510. The first LED 526 is formed on the first cathode 522a. The first LED 526 may comprise any suitable number of n-type layers, p-type layers, active layers, and tunnel junctions.

In one or more embodiments, the n-type layers and p-type layers of the first LED 526 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the first LED 526 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the first LED 526 may be doped or undoped and have any suitable thickness.

In one or more embodiments, first LED 526 is manufactured by placing the substrate 502 in a metalorganic vapor-phase epitaxy (MOVPE) reactor so that the µLED array layers are grown epitaxially.

In one or more embodiments, the first LED 526 includes a first light-emitting active region. In one or more embodiments, the first LED 526 includes a first light-emitting active region that is a blue active region. The first light-emitting active region may include multiple quantum wells and may include electron blocking layer(s) grown after the quantum wells and strain-control layers grown before the quantum wells. The number of quantum wells typically used for blue LEDs ranges from 1 to 12, the typical barrier thickness ranges from 3 nm to 20 nm, the well thickness ranges from 1 nm to 5 nm, and the well indium concentration ranges from 10% indium to 20% indium. In some embodiments, the active region(s) may be doped with Si or Ge, while in other embodiments, the active region(s) is undoped.

Referring to FIG. 5, a first anode 520a is formed on the first LED 526. A current blocking layer 524 is the formed on the first anode 520a. In one or more embodiments, a second anode 520b is formed on the current blocking layer 524.

In one or more embodiments, a second LED 516 is formed on the second anode 520b. The second LED 516 may comprise any suitable number of n-type layers, p-type layers, active layers, and tunnel junctions.

In one or more embodiments, the n-type layers and p-type layers of the second LED 516 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the second LED 516 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the second LED 516 may be doped or undoped and have any suitable thickness.

In one or more embodiments, the second LED 516 includes a second light-emitting active region. In one or more embodiments, the second LED 516 includes a second light-emitting active region that is a green active region. A second cathode 522b is formed on the second LED 516. In one or more embodiments, a third cathode 522c is formed on the second cathode 522b, and a third LED 518 is formed on the third cathode 522c.

The third LED 518 may comprise any suitable number of n-type layers, p-type layers, active layers, and tunnel junctions. In one or more embodiments, the n-type layers and p-type layers of the third LED 518 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the third LED 518 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the third LED 518 may be doped or undoped and have any suitable thickness.

In one or more embodiments, the third LED 518 includes a third light-emitting active region. In one or more embodiments, the third LED 518 includes a third light-emitting active region that is a red active region. A third anode 520c is formed on the third LED 518.

Referring to FIG. 5, the FET transistors 560a, 560b, 560c of the device 500 includes the transistor channel layer 510, which extends between a source and drain region. A dielectric layer 506 is formed on the transistor channel layer 510 of the FET transistors 560a, 560b, 560c and on the RGB stack 550. Each of the FET transistors 560a, 560b, 560c includes a gate 512a, 512b, 512c on the dielectric layer 506. An anode 540 is formed on each FET transistor 560a, 560b, 560c, and an electrode terminal 544 is formed on each FET transistor 560a, 560b, 560c and connects to one of the LEDs of the RGB stack 550.

In one or more embodiments, a source FET can also be fabricated in the same way as the drive FET (or the “FET” described above). Each color LED (or the first or second or the third LED) will have one Drive FET (as shown in FIG. 5) and one or more Select FET to control the operation of the LED such as the drive current, pulse durations and turn on time. This can realize a monolithic device with LEDs and transistors on the sample epi wafer and therefore no need TFT or CMOS pixel drives.

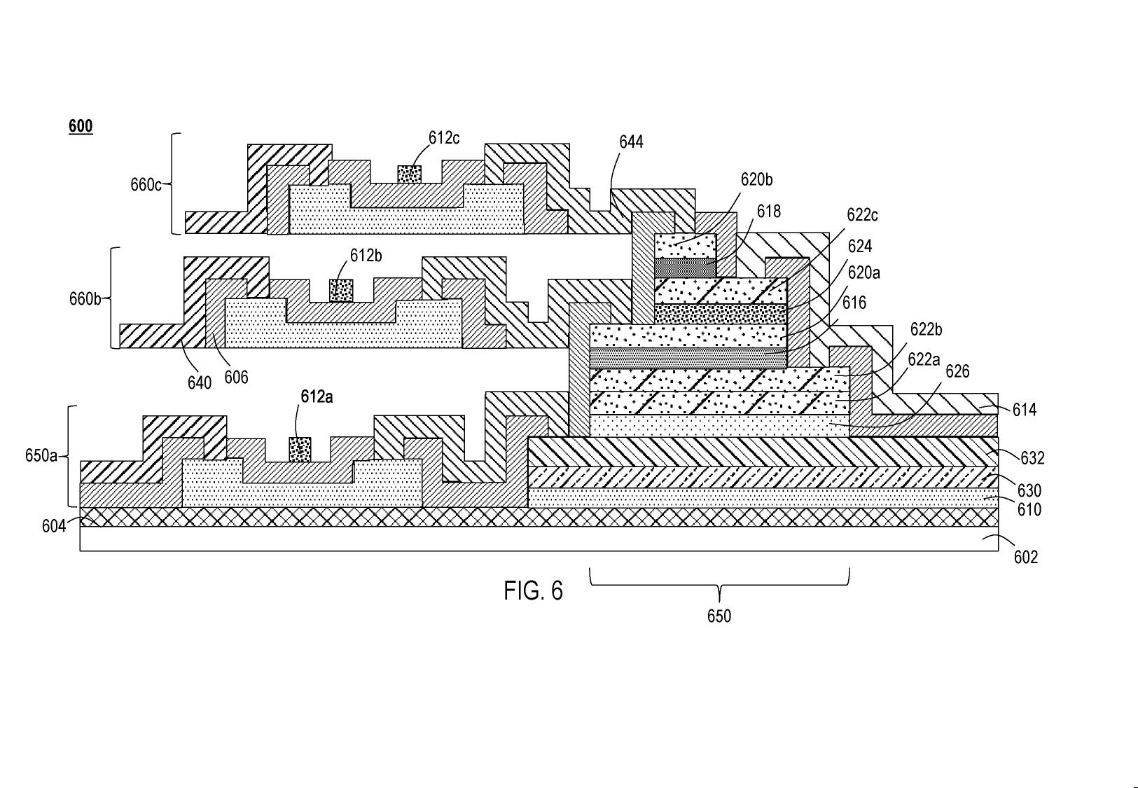

FIG. 6 shows a common cathode 614 connected to each RGB stack 650. In one or more embodiments, each LED of the RGB stack 650 is connected via an electrode terminal 644 to a FET transistor 660a, 660b, 660c to form the device 600. Advantageously, the device 600 does not need to be attached to a display backplane due to the presence of the FET transistors 660a, 660b, 660c on the same substate 602 as the RGB stack 650. Any other transistors, such as Select (or Scan) transistors, which control Drive transistors and any other additional transistors to compensate for the instability of the Drive transistors, can be fabricated in the same way on the same epi substrate. In one or more embodiments, there are four electrode terminals per RGB stack 650. Each RGB stack 650 has a single current blocking layer 624. Each FET transistor 660a, 660b, 660c also is connected to an anode terminal 640.

Referring to FIG. 6, an RGB stack 650 is formed on a substrate 602. In one or more embodiments, a nucleation layer 604 and dislocation density control layers (not illustrated) may be grown on a suitable substrate 602, such as patterned or non-patterned sapphire as described above. In one or more embodiments, the nucleation layer comprises a III-nitride material. In specific embodiments, the nucleation layer 604 comprises gallium nitride (GaN) or aluminum nitride (AlN).

A transistor channel layer 610 is then formed on the nucleation layer 604. The transistor channel layer 610 may comprise any suitable material known to the skilled artisan. In one or more embodiments, the transistor channel layer 610 comprises any Group III-V semiconductor material, including binary, ternary, and quaternary alloys of gallium (Ga), aluminum (Al), indium (In), and nitrogen (N), also referred to as III-nitride materials. In specific embodiments, the transistor channel layer 610 comprises gallium nitride (GaN).

In one or more embodiments a contact layer 630 is formed on the transistor channel layer 610. The contact layer 630 may comprise any suitable material known to the skilled artisan. In one or more embodiments, the contact layer 630 comprises any Group III-V semiconductor material, including binary, ternary, and quaternary alloys of gallium (Ga), aluminum (Al), indium (In), and nitrogen (N), also referred to as III-nitride materials. In specific embodiments, the contact layer 630 comprises gallium nitride (GaN).

In one or more embodiments, an anode layer 632 is formed on the contact layer 630. The anode layer 632 may comprise any suitable material known to the skilled artisan. In one or more embodiments, the anode layer 632 includes one or more tunnel junction.

The first LED 626 is formed on the anode layer 632. The first LED 626 may comprise any suitable number of n-type layers, p-type layers, active layers, and tunnel junctions.

In one or more embodiments, the n-type layers and p-type layers of the first LED 626 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the first LED 626 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the first LED 626 may be doped or undoped and have any suitable thickness.

In one or more embodiments, first LED 626 is manufactured by placing the substrate 602 in a metalorganic vapor-phase epitaxy (MOVPE) reactor so that the µLED array layers are grown epitaxially.

In one or more embodiments, the first LED 626 includes a first light-emitting active region. In one or more embodiments, the first LED 626 includes a first light-emitting active region that is a blue active region. The first light-emitting active region may include multiple quantum wells and may include electron blocking layer(s) grown after the quantum wells and strain-control layers grown before the quantum wells. The number of quantum wells typically used for blue LEDs ranges from 1 to 12, the typical barrier thickness ranges from 3 nm to 20 nm, the well thickness ranges from 1 nm to 5 nm, and the well indium concentration ranges from 10% indium to 20% indium. In some embodiments, the active region(s) may be doped with Si or Ge, while in other embodiments, the active region(s) is undoped.

Referring to FIG. 6, a first cathode 622a is formed on the first LED 626. A second cathode 622b is the formed on the first cathode 622a.

In one or more embodiments, a second LED 616 is formed on the second cathode 622b. The second LED 616 may comprise any suitable number of n-type layers, p-type layers, active layers, and tunnel junctions.

In one or more embodiments, the n-type layers and p-type layers of the second LED 616 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the second LED 616 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the second LED 616 may be doped or undoped and have any suitable thickness.

In one or more embodiments, the second LED 616 includes a second light-emitting active region. In one or more embodiments, the second LED 616 includes a second light-emitting active region that is a green active region. The second anode 620a is formed on the second LED 616.

In one or more embodiments, a current blocking layer 624 is formed on the second anode 620a.

In one or more embodiments, a third cathode 622c is formed on the current blocking layer 624, and a third LED 618 is formed on the third cathode 622c.

The third LED 618 may comprise any suitable number of n-type layers, p-type layers, active layers, and tunnel junctions. In one or more embodiments, the n-type layers and p-type layers of the third LED 618 may independently comprise any Group III-V semiconductor material, including binary, ternary, and quaternary alloys of gallium (Ga), aluminum (Al), indium (In), and nitrogen (N). Thus, in some embodiments, the n-type layers and p-type layers of the third LED 618 independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. The layers that make up the third LED 618 may be doped or undoped and have any suitable thickness.

In one or more embodiments, the third LED 618 includes a third light-emitting active region. In one or more embodiments, the third LED 618 includes a third light-emitting active region that is a red active region. A third anode 620b is formed on the third LED 618.

Referring to FIG. 6, the FET transistors 660a, 660b, 660c of the device 600 includes the transistor channel layer 610, which extends between a source and drain region. A dielectric layer 606 is formed on the transistor channel layer 610 of the FET transistors 660a, 660b, 660c and on the RGB stack 650. Each of the FET transistors 660a, 660b, 660c includes a gate 612a, 612b, 612c on the dielectric layer 606. An anode 640 is formed on each FET transistor 660a, 660b, 660c, and an electrode terminal 644 is formed on each FET transistor 660a, 660b, 660c and connects to one of the LEDs of the RGB stack 650.

In one or more embodiments, a source FET can also be fabricated in the same way as the drive FET (or the “FET” described above). Each color LED (or the first or second or the third LED) will have one Drive FET (as shown in FIG. 6) and one or more Select FET to control the operation of the LED such as the drive current, pulse durations and turn on time. This can realize a monolithic device with LEDs and transistors on the sample epi wafer and therefore no need TFT or CMOS pixel drives.

### EMBODIMENTS

Various embodiments are listed below. It will be understood that the embodiments listed below may be combined with all aspects and other embodiments in accordance with the scope of the invention.

Embodiment (a). A light-emitting diode (LED) device comprising: a polychromatic epitaxial stack on a substrate, the polychromatic epitaxial stack including a first light-emitting active region, a second light-emitting active region, a third light-emitting active region, and a first current blocking layer; and at least three field effect transistors (FET) electrically connected to one of the first light-emitting active region, the second light-emitting active region, or the third light-emitting active region.

Embodiment (b). The LED device of embodiment (a), wherein the first light-emitting active region, the second light-emitting active region, and the third light-emitting active region are electrically isolated from one another and independently comprise a blue active region, a green active region, or a red active region.

Embodiment (c). The LED device of embodiment (a) and embodiment (b), wherein the polychromatic epitaxial stack further comprises at least four terminals filled with one or more of an anode metal layer or a cathode metal layer.

Embodiment (d). The LED device of embodiment (a) to embodiment (c), wherein the cathode metal layer and the anode metal layer independently comprise one or more of aluminum (Al) or silver (Ag).

Embodiment (e). The LED device of embodiment (a) to embodiment (d), further comprising a dielectric layer in each of the four terminals.

Embodiment (f). The LED device of embodiment (a) to embodiment (e), wherein the at least one of the terminals comprises a common cathode.

Embodiment (g). The LED device of embodiment (a) to embodiment (f), wherein the at least one of the terminals comprises a common anode.

Embodiment (h). The LED device of embodiment (a) to embodiment (g), wherein the field effect transistors (FET) comprise a channel layer extending between a source and a drain on the substrate, a dielectric layer on the channel layer, and a gate on the dielectric layer.

Embodiment (i). The LED device of embodiment (a) to embodiment (h), further comprising a channel layer between the substrate and the polychromatic epitaxial stack.

Embodiment (j). The LED device of embodiment (a) to embodiment (i), wherein the channel layer comprises gallium nitride (GaN).

Embodiment (k). The LED device of embodiment (a) to embodiment (j), further comprising a second current blocking layer.

Embodiment (l). The LED device of embodiment (a) to embodiment (k), further comprising a nucleation layer on the substrate.

Embodiment (m). The LED device of embodiment (a) to embodiment (l), wherein the first current blocking layer comprises one or more of a p-type layer or an n-type layer.

Embodiment (n). A method of manufacturing a light-emitting diode (LED) device, the method comprising: epitaxially growing a polychromatic epitaxial stack on a substrate, the polychromatic epitaxial stack including a first light-emitting active region, a second light-emitting active region, a third light-emitting active region, and a first current blocking layer; and electrically connecting each of the first light-emitting active region, the second light-emitting active region, and the third light-emitting active region to a field effect transistor (FET).

Embodiment (o). The method of embodiment (n), wherein the first light-emitting active region, the second light-emitting active region, and the third light-emitting active region are electrically isolated from one another and independently comprise a blue active region, a green active region, or a red active region.

Embodiment (p). The method of embodiment (n) and embodiment (o), wherein the polychromatic epitaxial stack further comprises at least four terminals filled with one or more of an anode metal layer or a cathode metal layer.

Embodiment (q). The method of embodiment (n) to embodiment (p), wherein the at least one of the terminals comprises a common cathode, or wherein the at least one of the terminals comprises a common anode.

Embodiment (r). The method of embodiment (n) to embodiment (q), wherein the field effect transistor (FET) comprises a channel layer extending between a source and a drain on the substrate, a dielectric layer on the channel layer, and a gate on the dielectric layer.

Embodiment (s). The method of embodiment (n) to embodiment (r), wherein the cathode metal layer and the anode metal layer independently comprise one or more of aluminum (Al) or silver (Ag).

Embodiment (t). The method of embodiment (n) to embodiment (s), further comprising forming a dielectric layer in each of the four terminals.

The use of the terms "a" and "an" and "the" and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., "such as") provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to the terms first, second, third, etc. may be used herein to describe various elements, and these elements should not be limited by these terms. These terms may be used to distinguish one element from another.

Reference throughout this specification to a layer, region, or substrate as being "on" or extending "onto" another element, means that it may be directly on or extend directly onto the other element or intervening elements may also be present. When an element is referred to as being "directly on" or extending "directly onto" another element, there may be no intervening elements present. Furthermore, when an element is referred to as being "connected" or "coupled" to another element, it may be directly connected or coupled to the other element and/or connected or coupled to the other element via one or more intervening elements. When an element is referred to as being "directly connected" or "directly coupled" to another element, there are no intervening elements present between the element and the other element. It will be understood that these terms are intended to encompass different orientations of the element in addition to any orientation depicted in the figures.

Relative terms such as "below," "above," "upper,", "lower," "horizontal" or "vertical" may be used herein to describe a relationship of one element, layer, or region to another element, layer, or region as illustrated in the figures. It will be understood that these terms are intended to encompass different orientations of the device in addition to the orientation depicted in the figures.

Reference throughout this specification to "one embodiment," "certain embodiments," "one or more embodiments" or "an embodiment" means that a particular feature, structure, material, or characteristic described in connection with the embodiment is included in at least one embodiment of the disclosure. Thus, the appearances of the phrases such as "in one or more embodiments," "in certain embodiments," "in one embodiment" or "in an embodiment" in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A light-emitting diode (LED) device comprising:
a polychromatic epitaxial stack on a substrate, the polychromatic epitaxial stack including a first light-emitting active region, a second light-emitting active region, a third light-emitting active region, and a first current blocking layer; and
at least three field effect transistors (FET) electrically connected to one of the first light-emitting active region, the second light-emitting active region, or the third light-emitting active region.

2. The LED device of claim 1, wherein the first light-emitting active region, the second light-emitting active region, and the third light-emitting active region are electrically isolated from one another and independently comprise a blue active region, a green active region, or a red active region.

3. The LED device of claim 1, wherein the polychromatic epitaxial stack further comprises at least four terminals filled with one or more of an anode metal layer or a cathode metal layer.

4. The LED device of claim 3, wherein the cathode metal layer and the anode metal layer independently comprise one or more of aluminum (Al) or silver (Ag).

5. The LED device of claim 3, further comprising a dielectric layer in each of the four terminals.

6. The LED device of claim 3, wherein the at least one of the terminals comprises a common cathode.

7. The LED device of claim 3, wherein the at least one of the terminals comprises a common anode.

8. The LED device of claim 1, wherein the field effect transistors (FET) comprise a channel layer extending between a source and a drain on the substrate, a dielectric layer on the channel layer, and a gate on the dielectric layer.

9. The LED device of claim 1, further comprising a channel layer between the substrate and the polychromatic epitaxial stack.

10. The LED device of claim 9, wherein the channel layer comprises gallium nitride (GaN).

11. The LED device of claim 1, further comprising a second current blocking layer.

12. The LED device of claim 1, further comprising a nucleation layer on the substrate.

13. The LED device of claim 1, wherein the first current blocking layer comprises one or more of a p-type layer or an n-type layer.

14. A method of manufacturing a light-emitting diode (LED) device, the method comprising:
epitaxially growing a polychromatic epitaxial stack on a substrate, the polychromatic epitaxial stack including a first light-emitting active region, a second light-emitting active region, a third light-emitting active region, and a first current blocking layer; and
electrically connecting each of the first light-emitting active region, the second light-emitting active region, and the third light-emitting active region to a field effect transistor (FET).

15. The method of claim 14, wherein the first light-emitting active region, the second light-emitting active region, and the third light-emitting active region are electrically isolated from one another and independently comprise a blue active region, a green active region, or a red active region.

16. The method of claim 14, wherein the polychromatic epitaxial stack further comprises at least four terminals filled with one or more of an anode metal layer or a cathode metal layer.

17. The method of claim 16, wherein the at least one of the terminals comprises a common cathode, or wherein the at least one of the terminals comprises a common anode.

18. The method of claim 14, wherein the field effect transistor (FET) comprises a channel layer extending between a source and a drain on the substrate, a dielectric layer on the channel layer, and a gate on the dielectric layer.

19. The method of claim 16, wherein the cathode metal layer and the anode metal layer independently comprise one or more of aluminum (Al) or silver (Ag).

20. The method of claim 16, further comprising forming a dielectric layer in each of the four terminals.
